(19) United States
(12) Patent Application Publication
(10) Pub. No.: US 2003/0206446 A1
(43) Pub. Date: Nov. 6, 2003

(54) System for setting reference cell threshold voltage in a memory device

(76) Inventor: Shigekazu Yamada, Tokyo (JP)

Correspondence Address: Daniel D. Tagliaferri, Coudert Brothers, Third Floor, 600 Beach Street, San Francisco, CA, 94109, US

(21) Appl. No.: 10/137,779

(22) Filed: May 1, 2002

(51) Int. Cl. G11C 16/04

(52) U.S. Cl. 365/185.24

(57) ABSTRACT

System for setting reference cell threshold voltage of a memory device. The memory device includes a plurality of core cells and first and second reference cells all coupled to a common word line. The method comprises steps of programming the first reference cell to a first voltage threshold level that is centered within a data bit “1” distribution of the core cells, and programming the second reference cell to a second voltage threshold level that is centered within a data bit “0” distribution of the core cells.

### FIELD OF THE INVENTION

The present invention relates to semiconductor memory devices, and more particularly, to a system for setting a reference cell voltage in a memory device.

### BACKGROUND OF THE INVENTION

Semiconductor devices, such as memory devices, are commonly used as information storage devices in digital systems. As the amount of information that needs to be stored increases, it has become increasingly important to have an efficient way of accessing such memory devices.

Generally, memory read or write operations are initiated in response to external signals provided to the memory by a controller, such as a processor. In most cases, the amount of information that needs to be transferred during a memory access is large. In addition, the rate at which the information is propagated from a processor to a memory device and vice versa continues to increase. Therefore, increasing performance demands are being placed on the ability to read and write information to memory devices.

In a FLASH memory, there is a technique to place reference cells in the core array area. As a result, the condition of the reference cells can follow that of their associated core cells. Thus, if it is desired to program a core cell, a reference cell on the same word line can be programmed as well. The reference cells can then be used during memory read operations.

FIG. 1 shows a diagram of core memory cells and reference cells associated with a word line in a memory device. The word line 102 is coupled to core memory cells 104 in addition to reference cells A and B. The reference cells are used during core cell read operations.

FIG. 2 shows data “1” and data “0” bit distributions of the core cells and the voltage threshold (Vth) levels of reference cells (A and B). For example, the average current flowing through the reference cells is used for comparison in a sensing circuit during read operations. However, if the two reference cells are not properly set, the average current will not be in the middle of the data “1” and data “0” distributions of the core cells. For example, since the Vth of the reference cells (A and B) are not properly set in the middle of the bit distributions, their average (shown at 202) will not be centered between the bit distributions. Thus, the optimal read margin to obtain the best memory performance will not be achieved.

Therefore, it would be desirable to have a way to set the voltage thresholds of reference cells in a core array to achieve the optimal read margin and best memory performance.

### SUMMARY OF THE INVENTION

The present invention includes a system for setting voltage threshold (Vth) levels of reference cells used in a memory device. As a result of the operation of the invention, the reference cells will have voltage threshold levels so that when averaging the current flowing through the reference cells for comparison in a sense circuit, the optimal read margin is achieved.

In one embodiment of the present invention, a method is provided for setting voltage threshold levels in a memory device that includes a plurality of core cells and first and second reference cells all coupled to a common word line. The method comprises steps of programming the first reference cell to a first voltage threshold level that is substantially centered within a data bit “1” distribution of the core cells, and programming the second reference cell to a second voltage threshold level that is substantially centered within a data bit “0” distribution of the core cells.

In another embodiment of the present invention, a method is provided for setting voltage threshold levels in a dual-bit flash memory device that includes a plurality of core cells and first and second reference cells all coupled to a common word line. The core cells includes four bit distributions defined as (0,0), (0,1), (1,0), and (1,1). The method comprises steps of programming the first reference cell to a first voltage threshold level that is substantially at one edge of the (1,0) distribution of the core cells, and programming the second reference cell to a second voltage threshold level that is substantially another edge of the (0,1) distribution of the core cells.

### BRIEF DESCRIPTION OF THE DRAWINGS

The foregoing aspects and the attendant advantages of this invention will become more readily apparent by reference to the following detailed description when taken in conjunction with the accompanying drawings wherein:

FIG. 1 shows a diagram of core memory cells and reference cells associated with a word line in a memory device;

FIG. 2 shows data “1” and data “0” bit distributions of the core cells and the voltage threshold levels of the reference cells of FIG. 1;

FIG. 3 shows data “1” and “0” bit distributions and the Vth levels of the two reference cells of after being programmed in accordance with the present invention;

FIG. 4 shows bit distributions for a double bit cell Flash memory; and

FIG. 5 shows program verify levels for two reference cells in a double bit Flash memory in accordance with the present invention.

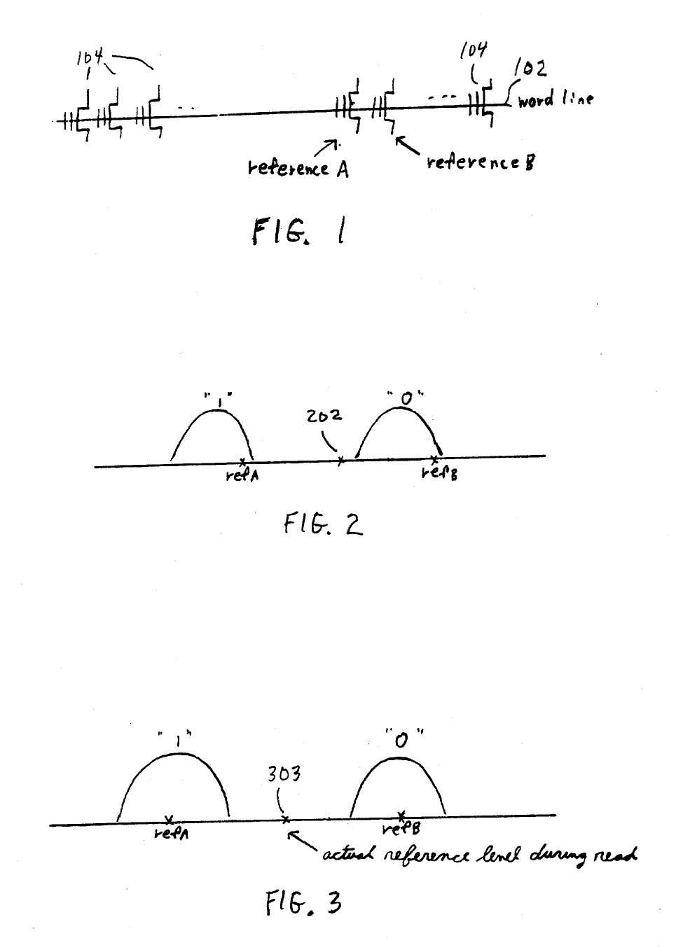

### DETAILED DESCRIPTION OF THE INVENTION

The present invention includes a system for setting voltage threshold levels of reference cells used in a memory device.

Exemplary Embodiment

In one embodiment of the invention, the Vth levels of reference cells associated with core memory cells are set in the middle of the data “0” and data “1” bit distributions in order to achieve the optimal read margin. The Vth levels for the reference cells are individually verified to achieve the desired Vth levels. In another embodiment, in a dual bit memory, the Vth levels of reference cells are set at selected levels with respect to the dual-bit distributions to achieve the desired read margin.

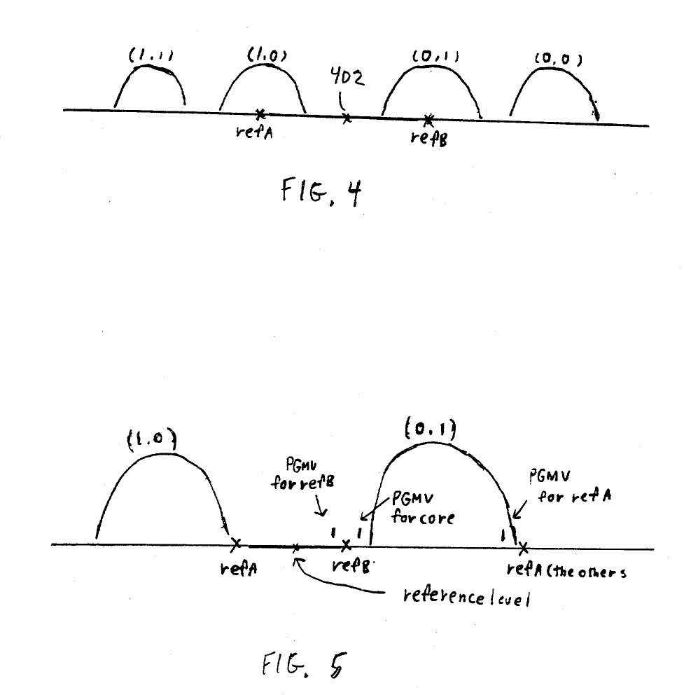

FIG. 3 shows data “1” and “0” bit distributions and the Vth levels of the two reference cells of after being programmed in accordance with the present invention. For example, reference A is now programmed to be in the middle of the data “1” distribution and reference B is programmed to be in the middle of the data “0” distribution. As a result, the average of the two reference cells is in the middle of the data distributions, as shown at 303. Thus, with the reference cells A and B programmed in accordance with the present invention, the optimal core cell read margin is achieved.

Another embodiment included in the present invention can be applied to double bit cell Flash memories. Since the double bit cell has specific problems, such as bit disturb, charge loss, and so on, one or more embodiments included in the present invention are suitable for use and very effective with double bit cells.

FIG. 4 shows bit distributions for a double bit cell Flash memory. For example, the double bit cell has four data bit distributions defined as (1,1) (1,0) (0,1) and (0,0). To achieve the optimal average (shown at 402) during read operations, the reference A should be in the middle of (1,0) and reference B should be in the middle of (0,1). However, both reference cells are not always in the middle of these distributions, and so poor memory performance may result.

In accordance with the one or more embodiments included in the present invention, the reference cells have their own program verify levels that are different from verify levels for the core cells.

FIG. 5 shows program verify levels for two reference cells in a double bit Flash memory in accordance with the present invention. The program verify (PGMV) levels for the reference cells must be determined so that both reference cells can be programmed close to the edge of the (0,1) distribution, as shown. If they are set close to the edge, a very good read margin will be achieved.

In accordance with the invention, both reference cells must be programmed slowly in order to program them accurately. In the double bit cell architecture with a technique to place reference cells in core array areas, one reference cell cannot be used to distinguish (1,0) form (0,1). Therefore, the averaging technique between reference A and reference B is necessary. When the averaging technique is used, the embodiments of the invention are especially suited to provide excellent results.

One or more embodiments of the present invention can be effectively used in the architecture of a dynamic reference, where reference cells are located in the core cell area with the word line and core cells. In accordance with one or more embodiments of the invention, the reference cells are programmed to different Vth levels from that of their respective core cells. Furthermore, the reference cells are programmed very accurately. In one embodiment, the reference cells are programmed using gentle programming pulses and the threshold levels are frequently verified to achieve the desired reference levels. For example, in one embodiment, gentle programming pulses are short pulses and/or low amplitude pulses that are used to program the reference cells in a process where the threshold levels are frequently verified. This makes it possible to achieve very accurate reference cell threshold level programming. Thus, gentle programming of the reference cells in one or more embodiments included in the present invention allows for efficiently setting the levels of the reference cells, which is used to achieve the best read margins.

The present invention includes a system for setting voltage threshold (Vth) levels of reference cells used in a memory device. The embodiments described above are illustrative of the present invention and are not intended to limit the scope of the invention to the particular embodiments described. Accordingly, while one or more embodiments of the invention have been illustrated and described, it will be appreciated that various changes can be made therein without departing from the spirit or essential characteristics thereof. Accordingly, the disclosures and descriptions herein are intended to be illustrative, but not limiting, of the scope of the invention, which is set forth in the following claims.

What is claimed is:

1. A method for setting voltage threshold levels in a memory device that includes a plurality of core cells and first and second reference cells all coupled to a common word line, the method comprising steps of:
programming the first reference cell to a first voltage threshold level that is substantially centered within a data bit “1” distribution of the core cells; and
programming the second reference cell to a second voltage threshold level that is substantially centered within a data bit “0” distribution of the core cells.

2. The method of claim 1, wherein the step of programming the first reference cell comprises steps of;
programming the first reference cell with gentle programming pulses; and
verifying the first voltage threshold level a plurality of times during the step of programming.

3. The method of claim 2, wherein the step of programming the second reference cell comprises steps of;
programming the second reference cell with gentle programming pulses; and
verifying the second voltage threshold level a plurality of times during the step of programming.

4. A method for setting voltage threshold levels in a dual-bit flash memory device that includes a plurality of core cells and first and second reference cells all coupled to a common word line, the core cells includes four bit distributions defined as (0,0), (0,1), (1,0), and (1,1), the method comprising steps of:
programming the first reference cell to a first voltage threshold level that is substantially at one edge of the (1,0) distribution of the core cells; and
programming the second reference cell to a second voltage threshold level that is substantially another edge of the (0,1) distribution of the core cells.

5. The method of claim 4, wherein the step of programming the first reference cell comprises steps of;
programming the first reference cell with gentle programming pulses; and
verifying the first voltage threshold level a plurality of times during the step of programming.

6. The method of claim 5, wherein the step of programming the second reference cell comprises steps of;
programming the second reference cell with gentle programming pulses; and
verifying the second voltage threshold level a plurality of times during the step of programming.

7. The method of claim 6, further comprising a step of programming the first and second reference cells to have different threshold levels than the core cells.
